(19) United States
(12) Patent Application Publication
(10) Pub. No.: US 2025/0389053 A1
(43) Pub. Date: Dec. 25, 2025

(54) Manufacturing Process of Plant-Derived Crystals, Jewels, and/or Jewelry

(71) Applicant: Paul Conrad Peterson, Troutdale, OR (US)

(72) Inventor: Paul Conrad Peterson, Troutdale, OR (US)

(21) Appl. No.: 19/242,549

(22) Filed: Jun. 18, 2025

Related U.S. Application Data
(60) Provisional application No. 63/662,581, filed on Jun. 21, 2024.

(51) Int. Cl. C30B 29/54; A44C 27/00

(52) U.S. Cl. CPC C30B 29/54; A44C 27/00

(57) ABSTRACT

This invention relates to a method for producing plant-derived or synthetic crystals suitable for use in jewelry and ornamental products. The process transforms organic or synthetic input material into crystalline structures through a multi-stage process involving extraction, purification, crystallization, solidification, curing, and final shaping. The invention allows for bulk or finished crystal production, with improved purity and structural integrity through repeatable, scalable methods. The approach minimizes environmental impact by using sustainable raw materials and energy-efficient processing techniques.

### CROSS-REFERENCE TO RELATED APPLICATIONS

This application claims priority to U.S. Provisional Application No. 63/662,581, filed Jun. 21, 2024, the contents of which are hereby incorporated by reference

### SPECIFICATION

### Field of the Invention

The present invention relates to the manufacturing of crystals, jewels, and jewelry derived from organic or synthetic material. More specifically, it concerns a scalable process for transforming biologically based or synthetic feedstock into crystal forms suitable for ornamental or functional use.

### BACKGROUND OF THE INVENTION

Traditional gems, jewel, and pearl production relies on environmentally destructive mining and harvesting methods. These techniques extract materials from natural ecosystems such as mountains and oceans, often leaving irreversible environmental damage. Current alternatives, including lab-grown gems, remain heavily dependent on synthetic chemistry, energy-intensive environments, and proprietary platforms. There is a need for a more sustainable, plant-derived alternative that can provide the same ornamental value without ecological destruction.

### SUMMARY OF THE INVENTION

This invention provides a novel and scalable method for producing solid crystalline materials from organic, plant-based, or synthetic inputs. The invention includes a multistage process that converts the source material into a usable extract, purifies the extract, initiates crystallization, and completes product finishing. The method enables the creation of both bulk and jewelry-grade crystal materials with potential for commercial, individual, or industrial applications.

### Advantages of the Invention

The present invention offers multiple distinct advantages over conventional gemstone, jewel, and crystal manufacturing methods, including:
1. Environmental Sustainability
2. Ethical Material Sourcing
3. Customizable Aesthetic and Functional Properties
4. Scalability Across Market Segments
5. Process Efficiency and Repeatability
6. Broad Material Input Compatibility
7. Patent-Protected Moat Around Plant-Based Crystallization
8. Temperature Stability and Longevity
9. Brand-Aligned Traceability and Differentiation

### BRIEF DESCRIPTION OF THE DRAWINGS

FIG. 1 shows a flowchart of the overall manufacturing process (102-120).

FIG. 2 illustrates the extraction and purification stage, including input material (101), extractor (102), and purifier (104).

FIG. 3 shows the crystallization chamber (110) and formed crystals (112).

FIG. 4 depicts isolation of the liquid (134), solidification unit (114), and storage container (116).

FIG. 5 shows shaping (118) and setting (120) of the final product.

### DETAILED DESCRIPTION OF THE INVENTION

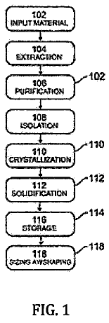

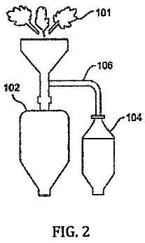

As shown in FIG. 1, the process begins with input material (102), such as plant-based biomass or synthetic analogs (101 in FIG. 2). This material is subjected to an extraction phase (104 in FIG. 1 and FIG. 2), where it is transformed into a usable extract or oil using mechanical or chemical methods. Purification (106 in FIG. 1 and FIG. 2) follows, removing unwanted lipids, waxes, and impurities.

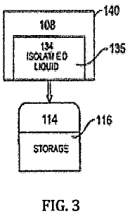

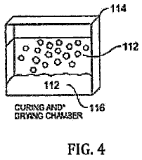

The purified extract is then isolated (108 in FIG. 1 and FIG. 4) into a stabilized environment (135) as shown by the container (140), producing an isolated liquid (134). This is subjected to a crystallization process (110 in FIG. 1 and FIG. 3), forming crystals (112), which are stabilized through solidification (112 and 114).

These crystals are cured and dried in a controlled environment (114 and 116 in FIG. 4), then stored in a chamber (116) with regulated conditions for long-term preservation.

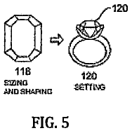

Finally, as illustrated in FIG. 5, the cured crystals are shaped and sized (118), and set (120) into final form products such as jewelry or decorative pieces.

1. A method for producing a solid crystalline material from organic or synthetic input matter, comprising: converting the input matter into an extract, oil, or liquid form using mechanical, thermal, or chemical means; removing impurities from the extract using a purification process; isolating the refined extract in a controlled environment; initiating a crystallization process under defined conditions to form a crystalline structure; stabilizing and solidifying the formed crystals to increase structural integrity and longevity; curing and/or drying the stabilized crystals; storing the crystals at a regulated temperature to maintain stability; shaping and sizing the crystals for application; and setting the shaped crystals into a finished product.

2. The method of claim 1, wherein the purification process includes the removal of lipids, waxes, and fats to improve crystalline quality.

3. The method of claim 1, wherein the crystallization process is repeated in multiple cycles to increase purity and achieve a desired hardness measured by Mohr scale values.

4. The method of claim 1, wherein the crystalline material is extracted through an evacuation port of sufficient diameter to minimize mechanical damage to the crystal structure.

5. The method of claim 1, wherein the final crystalline output is selected from the group consisting of randomly sized crystals, uniformly sized crystals, bulk unfinished crystals, and jewelry-grade finished crystals.

6. The method of claim 1, wherein the input matter comprises one or more of: lignocellulosic plant biomass, hemp stalks, plant-derived resins, or synthetic polymer analogs.
